(19) United States
(12) Patent Application Publication
(10) Pub. No.: US 2026/0271738 A1
(43) Pub. Date: Sep. 10, 2026

(54) TRANSFER MOLDED MODULE

(71) Applicant: Mitsubishi Electric Corporation, Tokyo (JP)

(72) Inventors: Takafumi KUSABA, Tokyo (JP); Hidetoshi YAMAKAWA, Tokyo (JP)

(73) Assignee: Mitsubishi Electric Corporation, Tokyo (JP)

(21) Appl. No.: 19/398,995

(22) Filed: Nov. 24, 2025

(30) Foreign Application Priority Data
Mar. 10, 2025 (JP) 2025-037699

(51) Int. Cl. H10W 44/00

(52) U.S. Cl. CPC H10W 44/401; H10W 70/442; H10W 74/00; H10W 90/811

(57) ABSTRACT

A transfer molded module includes: a p-side frame; an n-side frame; a high-side first power device connected to the p-side frame; a low-side second power device connected to the n-side frame; a monitoring terminal; a resistor connected between the p-side frame and the monitoring terminal; and an encapsulating resin encapsulating the p-side frame, the n-side frame, the first power device, the second power device, the monitoring terminal, and the resistor, wherein the p-side frame, the n-side frame, and the monitoring terminal are led out from a side surface of the encapsulating resin.

### BACKGROUND OF THE INVENTION

### Field

The present disclosure relates to a transfer molded module.

### Background

In a semiconductor module for controlling a motor, a drive ability of the motor changes depending on a magnitude of a bus voltage, and hence monitoring of the bus voltage is important. However, the bus voltage is large, and hence cannot be directly monitored by a microcontroller. In view of the above, in the related art, a voltage dividing resistor provided on a control board outside of the module is connected to a bus of the module to divide the bus voltage, and the microcontroller monitors the divided bus voltage (see, for example, Patent Literature 1).

### Citation List

### Patent Literature

Patent Literature 1: JP 2012-039683 A

### SUMMARY

### Technical Problem

The heat dissipation property of the resistor provided on the control board is bad, and hence there has been a problem in that the monitoring accuracy of the bus voltage is reduced.

The present disclosure has been made to solve the above-mentioned problem, and has an object to provide a transfer molded module that makes it possible to improve a monitoring accuracy of a bus voltage.

### Solution to Problem

A transfer molded module according to the present disclosure includes: a p-side frame; an n-side frame; a high-side first power device connected to the p-side frame; a low-side second power device connected to the n-side frame; a monitoring terminal; a resistor connected between the p-side frame and the monitoring terminal; and an encapsulating resin encapsulating the p-side frame, the n-side frame, the first power device, the second power device, the monitoring terminal, and the resistor, wherein the p-side frame, the n-side frame, and the monitoring terminal are led out from a side surface of the encapsulating resin.

### Advantageous Effects of Invention

In the present disclosure, the resistor for monitoring the bus voltage is provided inside the module, and hence the heat of the resistor can also be dissipated from the heat dissipation surface of the module. As a result, the monitoring accuracy of the bus voltage is improved.

### BRIEF DESCRIPTION OF DRAWINGS

FIG. 1 is a plan view illustrating a transfer molded module according to a first embodiment.

FIG. 2 is a circuit diagram illustrating the transfer molded module according to the first embodiment.

FIG. 3 is a sectional view illustrating the transfer molded module according to the first embodiment.

FIG. 4 is a sectional view illustrating a semiconductor device according to the first embodiment.

FIG. 5 is a block diagram illustrating the semiconductor device according to the first embodiment.

FIG. 6 is a block diagram illustrating a semiconductor device according to the comparative example.

FIG. 7 is a plan view illustrating a modification example of the transfer molded module according to the first embodiment.

FIG. 8 is a plan view illustrating a transfer molded module according to a second embodiment.

FIG. 9 is a circuit diagram illustrating the transfer molded module according to the second embodiment.

FIG. 10 is a sectional view illustrating the transfer molded module according to the second embodiment.

FIG. 11 is a plan view illustrating a modification example of the transfer molded module according to the second embodiment.

FIG. 12 is a sectional view illustrating a semiconductor device according to a third embodiment.

FIG. 13 is a sectional view illustrating a semiconductor device according to a fourth embodiment.

### DESCRIPTION OF EMBODIMENTS

A transfer molded module according to the embodiments of the present disclosure will be described with reference to the drawings. The same components will be denoted by the same symbols, and the repeated description thereof may be omitted.

### First Embodiment

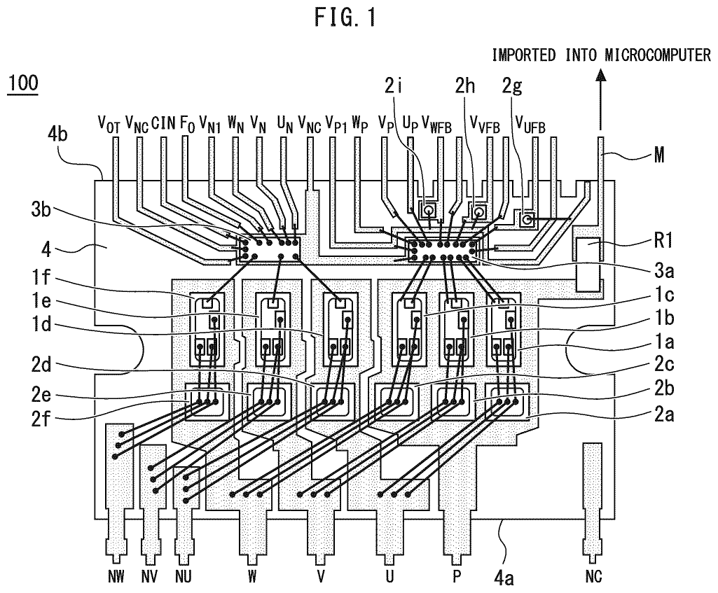

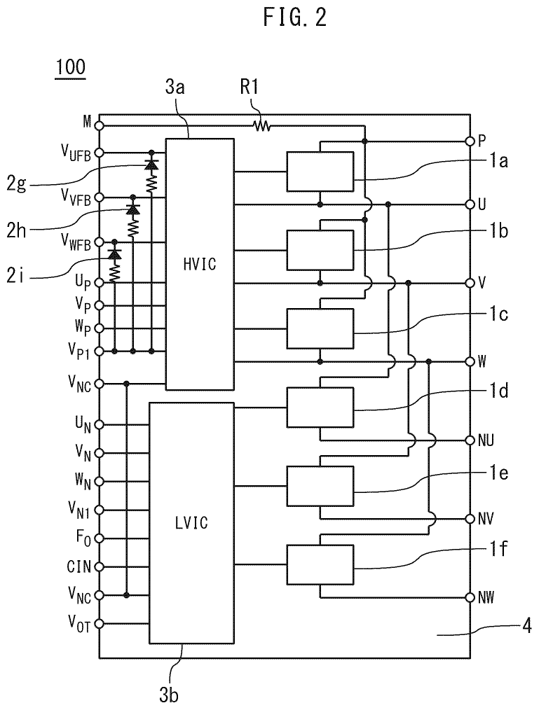

FIG. 1 is a plan view illustrating a transfer molded module according to a first embodiment. FIG. 2 is a circuit diagram illustrating the transfer molded module according to the first embodiment. This module 100 is an intelligent power module (IPM) obtained by modularizing power devices 1a to 1f, diodes 2a to 2f, and first and second control devices 3a and 3b as one electronic component. The power devices 1a to 1f and the diodes 2a to 2f configure an inverter that converts a DC voltage into a three-phase AC.

The power devices 1a, 1b, and 1c are an upper arm of the three-phase inverter. The power devices 1d, 1e, and 1f are a lower arm of the three-phase inverter. The power devices 1a to 1f are, for example, insulated-gate bipolar transistors (IGBTs), but may be field effect transistors. It is to be noted that the circuit configuration of this embodiment is a 6-in-1 configuration in which the power devices 1a to 1f corresponding to three phases are arranged in parallel, but the circuit configuration is not limited thereto and may be a 2-in-1 configuration or the like.

Each of the diodes 2a to 2f is a freewheeling diode connected in antiparallel to a corresponding one of the power devices 1a to 1f. The first control device 3a is an HVIC (high voltage integrated circuit) that controls the high-side power devices 1a, 1b, and 1c. The second control device 3b is an LVIC (low voltage integrated circuit) that controls the low-side power devices 1d, 1e, and 1f.

Terminals P, U, V, W, NU, NV, NW, NC, V_{UFB}, V_{VFB}, V_{WFB}, U_{P}, V_{P}, W_{P}, V_{P1}, V_{NC}, U_{N}, V_{N}, W_{N}, V_{N1}, Fₒ, CIN, V_{NC}, and V_{OT} and a monitoring terminal M are lead frames. The terminals P, U, V, W, NU, NV, and NW are power output terminals, and the terminals U_{P}, V_{P}, W_{P}, U_{N}, V_{N}, W_{N} and the like are control terminals. The power output terminals and the control terminals extend in directions opposite to each other. The power output terminals and the control terminals are formed by processing one lead frame, but may be different members. The terminal P is a p-side frame. The terminals U, V, and W are n-side frames.

The high-side power devices 1a, 1b, and 1c and the diodes 2a, 2b, and 2c are mounted on a die pad portion of the terminal P. Collectors of the power devices 1a, 1b, and 1c and cathodes of the diodes 2a, 2b, and 2c are connected to the terminal P. The low-side power device 1d and the diode 2d are mounted on a die pad portion of the terminal U. A collector of the power device 1d and a cathode of the diode 2d are connected to the terminal U. The low-side power device 1e and the diode 2e are mounted on a die pad portion of the terminal V. A collector of the power device 1e and a cathode of the diode 2e are connected to the terminal V. The low-side power device 1f and the diode 2f are mounted on a die pad portion of the terminal W. A collector of the power device 1f and a cathode of the diode 2f are connected to the terminal W.

An emitter of the power device 1a, an anode of the diode 2a, and the terminal U are wire-connected in order. An emitter of the power device 1b, an anode of the diode 2b, and the terminal V are wire-connected in order. An emitter of the power device 1c, an anode of the diode 2c, and the terminal W are wire-connected in order. An emitter of the power device 1d, an anode of the diode 2d, and the terminal NU are wire-connected in order. An emitter of the power device 1e, an anode of the diode 2e, and the terminal NV are wire-connected in order. An emitter of the power device 1f, an anode of the diode 2f, and the terminal NW are wire-connected in order. The terminal NC is a terminal having no internal connection.

The first and second control devices 3a and 3b are mounted on a die pad portion of the terminal V_{NC}. Back electrodes of the power devices 1a to 1f, the diodes 2a to 2f, and the first and second control devices 3a and 3b are each joined to the die pad portion of the lead frame via a conductive joining material such as solder.

An output terminal of the first control device 3a is wire-connected to a gate of each of the power devices 1a, 1b, and 1c. An output terminal of the second control device 3b is wire-connected to a gate of each of the power devices 1d, 1e, and 1f. The first control device 3a controls an operation of each of the power devices 1a, 1b, and 1c. The second control device 3b controls an operation of each of the power devices 1d, 1e, and 1f.

The first control device 3a is wire-connected to each of the terminals V_{UFB}, V_{VFB}, V_{WFB}, U_{P}, V_{P}, W_{P}, V_{P1}, and V_{NC}. The terminal V_{P1} is a power supply terminal. The terminals V_{UFB}, V_{VFB}, and V_{WFB} are P-side drive power supply voltage terminals. The terminals U_{P}, V_{P}, and W_{P} are first control terminals that input control signals from the external microcontroller to the first control device 3a. The terminal V_{NC} is a ground terminal.

The second control device 3b is wire-connected to each of the terminals U_{N}, V_{N}, W_{N}, V_{N1}, Fₒ, CIN, V_{NC}, and V_{OT}. The terminals U_{N}, V_{N}, and W_{N} are second control terminals that input control signals from the external microcontroller to the second control device 3b. The terminal Fₒ is an error signal output terminal that outputs an error signal. The terminal V_{NC} is a grounded ground terminal. When a signal is input to the terminal CIN at the time of short-circuit detection, the second control device 3b shuts off the power devices of the lower arm.

A diode 2g is mounted on the terminal V_{UFB}. A cathode of the diode 2g is connected to the terminal V_{UFB}. An anode of the diode 2g is wire-connected to the terminal V_{P1}. A diode 2h is mounted on the terminal V_{VFB}. A cathode of the diode 2h is connected to the terminal V_{VFB}. An anode of the diode 2h is wire-connected to the terminal V_{P1}. A diode 2i is mounted on the terminal V_{WFB}. A cathode of the diode 2i is connected to the terminal V_{WFB}. An anode of the diode 2i is wire-connected to the terminal V_{P1}.

The material of the wire is, for example, one of metals such as aluminum (Al), copper (Cu), gold (Au), and silver (Ag), or an alloy material containing at least one thereof. When a wire is thin, it is possible to reduce the size of the pad portion at which wire bonding is performed, which makes it possible to downsize the first control device 3a and the second control device 3b. Thus, wires connected to the first control device 3a and the second control device 3b are thin metal wires having a diameter of 50 μm or less. Further, wires connected to the power devices 1a to 1f are thicker than the thin metal wires, and are thick metal wires having a diameter of, for example, 100 μm or more. It is to be noted that, as long as the metal wire has a diameter corresponding to a current flowing through the metal wire, other metal wires may be used. For example, when a small current flows through the metal wire, a metal wire thinner than the thick metal wire may be used as the metal wire. Further, the number of metal wires may be one or more as long as the current density of the current flowing through the cross section of the metal wire is an allowable value or less.

The diodes 2g, 2h, and 2i are boost diodes used for charging externally-attached bootstrap capacitors (not shown). The bootstrap capacitors cover the power consumption of the first control device 3a. With the boost diode being mounted in the module, no boost diode is required to be mounted outside of the module, and hence it is possible to downsize the substrate area of the semiconductor device.

As a configuration for monitoring the bus voltage of the terminal P, a resistor R1 is connected between the terminal P and the monitoring terminal M. The resistance value of the resistor R1 is 1 to 2 MΩ. It is to be noted that the resistor R1 is a chip resistor. Two electrodes of the chip resistor are respectively soldered to the terminal P and the monitoring terminal M. The two electrodes are preferably provided on short sides of a rectangular chip resistor. This makes an electrode-to-electrode distance long, and a short circuit is less liable to occur between the electrodes at the time of soldering. It is to be noted that the resistor R1 is not limited to a chip resistor, and may be a lead resistor, a coil resistor, or the like.

An encapsulating resin 4 encapsulates the power devices 1a to 1f, the diodes 2a to 2i, the first and second control devices 3a and 3b, the resistor R1, the terminals, and the wires. The encapsulating resin 4 is formed by loading an uncured epoxy resin into a mold for transfer molding and curing the epoxy resin. The material of the encapsulating resin 4 is not limited to epoxy resin, and is only required to be a curable material having electrical insulation.

A distal end of each terminal is led out from a side surface of the encapsulating resin 4. Specifically, the encapsulating resin 4 includes a first side surface 4a and a second side surface 4b that are opposed to each other. The terminals P, U, V, W, and the like that are power terminals are led out from the first side surface 4a, and the terminals U_{P}, V_{P}, W_{P}, U_{N}, V_{N}, W_{N}, and the like that are control terminals and the monitoring terminal M are led out from the second side surface 4b.

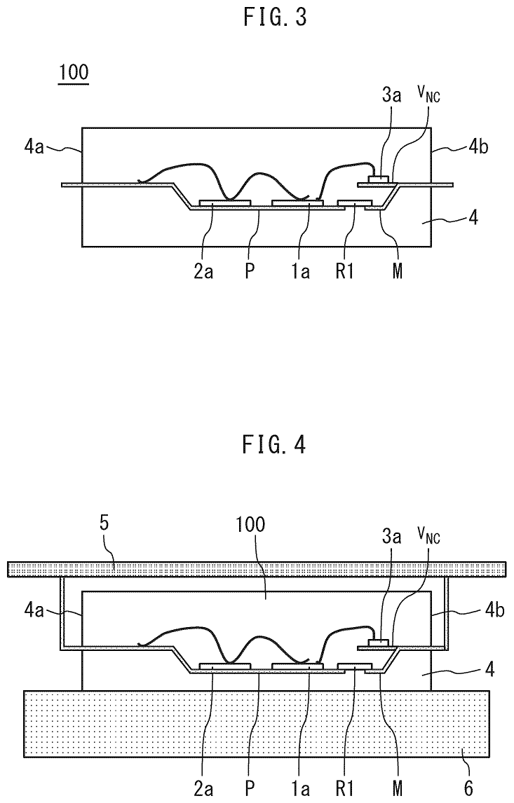

FIG. 3 is a sectional view illustrating the transfer molded module according to the first embodiment. The resistor R1 is joined to a part of the monitoring terminal M bent downward and the terminal P. In the encapsulating resin 4, the first and second control devices 3a and 3b are positioned to be higher than the power devices 1a to 1f, and the resistor R1 is positioned at the same height as the power devices 1a to 1f. The lower side of the terminals P, U, V, and W and the monitoring terminal M is covered with the encapsulating resin 4.

FIG. 4 is a sectional view illustrating a semiconductor device according to the first embodiment. A control board 5 is placed above the module. A terminal protruding from the side surface of the module 100 is connected to the control board 5. A heatsink 6 is attached to a heat dissipation surface of the module 100. Accordingly, the heat of the power devices 1a to 1f can be dissipated to the heatsink 6. Moreover, heat of the resistor R1 for monitoring the bus voltage can also be dissipated to the heatsink 6.

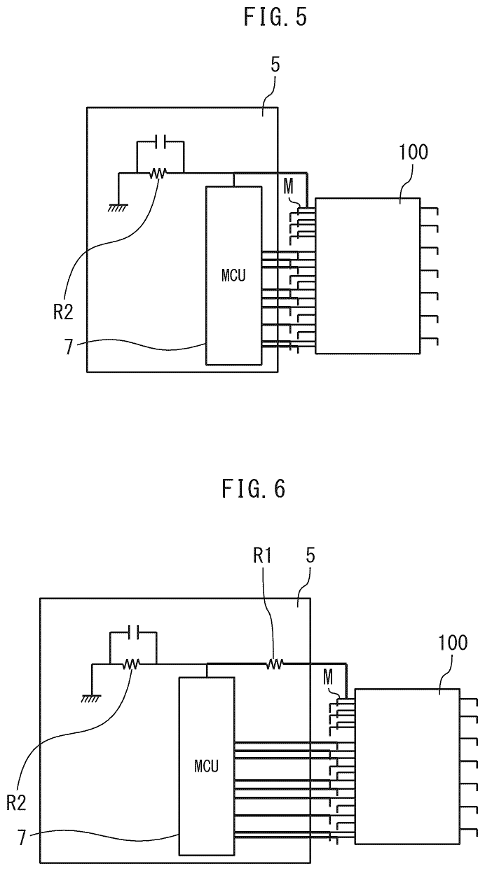

FIG. 5 is a block diagram illustrating the semiconductor device according to the first embodiment. The resistor R1 of 1 to 2 MΩ plays a role of a voltage dividing resistor for monitoring the bus voltage. Accordingly, it is only required to provide a voltage dividing resistor R2 on the ground side to the control board 5. It is only required that the voltage be divided down to a threshold value of 1.0 to 5.5 V of the microcontroller in accordance with the bus voltage, and hence, for example, when the bus voltage is 566 V and the resistor R1 in the module is 2 MΩ, the voltage dividing resistor R2 is 10 kΩ.

Subsequently, an effect of this embodiment is described in comparison with a comparative example. FIG. 6 is a block diagram illustrating a semiconductor device according to the comparative example. In the comparative example, the resistor R1 for monitoring the bus voltage is provided on the control board 5. Thus, the heat dissipation property of the resistor R1 is bad, and hence the monitoring accuracy is reduced. In contrast, in this embodiment, the resistor R1 for monitoring the bus voltage is provided inside the module, and hence the heat of the resistor R1 can also be dissipated from the heat dissipation surface of the module. As a result, the monitoring accuracy of the bus voltage is improved. It is to be noted that heat generation of the resistor R1 affects the operations of the power devices 1a to 1f, and hence the resistor R1 is preferably placed at a module end to be separated apart from the power devices 1a to 1f.

Further, in the comparative example, a wiring distance between a microcontroller 7 and the module 100 is increased because the resistor R1 is present on the control board 5. In contrast, in this embodiment, the resistor R1 is provided inside the module, and hence the bus voltage can be directly monitored from the monitoring terminal M of the module. This eliminates the need to provide the resistor R1 on the control board 5, and hence the wiring distance between the microcontroller 7 and the module 100 is decreased to improve the monitoring accuracy of the bus voltage. Further, there is no need to provide the resistor R1 on the control board 5, which makes it possible to ensure a space on the board.

Further, the monitoring terminal M is led out from the second side surface 4b of the encapsulating resin 4 similarly to the terminals U_{P}, V_{P}, W_{P}, U_{N}, V_{N}, and W_{N} that are control terminals. Leading out the monitoring terminal M from the side on which the control terminals connected to the microcontroller 7 are present allows the routing distance of the wiring from the monitoring terminal M to the microcontroller 7 to be reduced. However, when the high-side power devices 1a, 1b, and 1c are turned on, the voltages of the terminals V_{UFB}, V_{VFB}, and V_{WFB} that are power supply terminals for driving the high side are increased as high as the bus voltage. Unless an insulating distance between those power supply terminals and the monitoring terminal M is ensured, a high voltage may be applied to the microcontroller 7 via the monitoring terminal M to damage the microcontroller 7. In view of the above, it is required to ensure an insulating distance between the power supply terminal and the monitoring terminal M at the second side surface 4b on the control terminal side.

Further, inside the encapsulating resin 4, the resistor R1 is positioned at the same height as the power devices 1a to 1f. This allows the resistor R1 to come closer to the heat dissipation surface of the module, and hence the heat dissipation property of the resistor R1 is improved to improve the monitoring accuracy. It is to be noted that, when the resistor R1 has a large size, the size of the heat dissipation surface is increased, and hence the resistor R1 is easily cooled.

Positioning the resistor R1 too close to a screw hole affects the fastening withstand amount, and positioning the resistor R1 close to the power devices 1a to 1f affects the monitoring accuracy by thermal interference. Accordingly, for example, it is preferred to prevent the resistor R1 from being positioned on a line connecting center portions of screw holes positioned on right and left sides of the module in plan view. Further, a RC-IGBT (Reverse Conducting-IGBT) in which a diode corresponding to the power device is integrated may be used. This makes it possible to downsize the module even when the resistor R1 is incorporated.

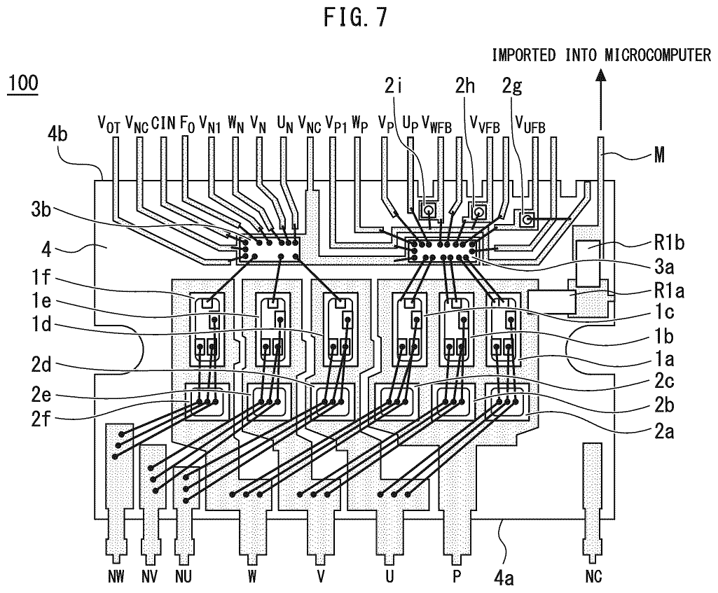

FIG. 7 is a plan view illustrating a modification example of the transfer molded module according to the first embodiment. In place of the resistor R1, a plurality of resistors R1a and R1b connected in series are provided. A resistance value of each of the resistors R1a and R1b is 1 to 2 MΩ. This makes it possible to monitor a high bus voltage even when a rated voltage or rated power is exceeded with a single resistor. Further, using a plurality of resistors R1a and R1b can avoid layout restrictions to be caused by the size of the chip resistor. It is to be noted that the resistor R1a may be positioned on the power output side and the resistor R1b may be positioned on the control terminal side, and both of them may be connected in series.

### Second Embodiment

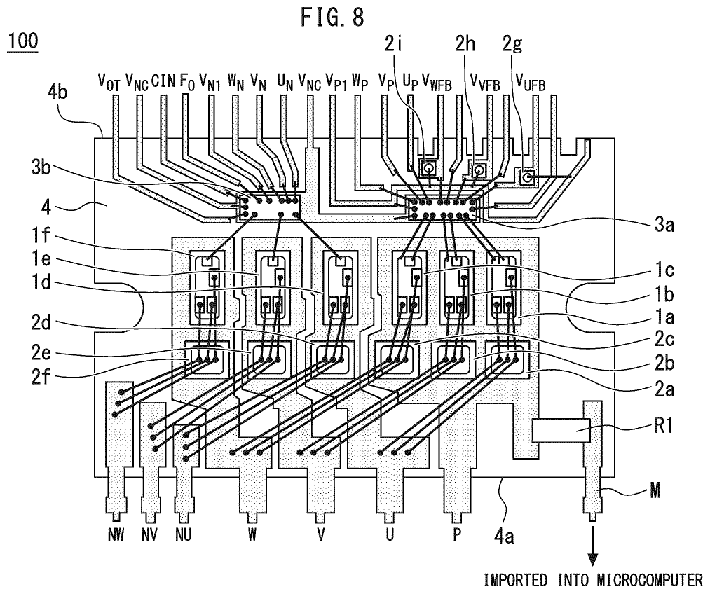

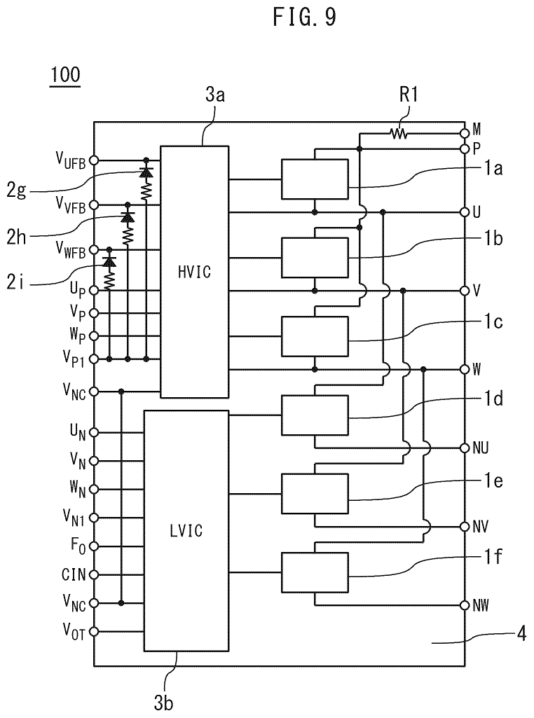

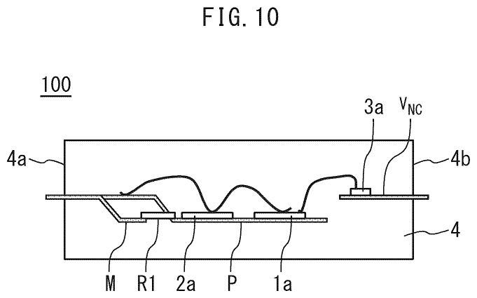

FIG. 8 is a plan view illustrating a transfer molded module according to a second embodiment. FIG. 9 is a circuit diagram illustrating the transfer molded module according to the second embodiment. FIG. 10 is a sectional view illustrating the transfer molded module according to the second embodiment. In this embodiment, the monitoring terminal M is led out from the first side surface 4a of the encapsulating resin 4 similarly to the terminals P, U, V, and W. The terminals U_{P}, V_{P}, W_{P}, U_{N}, V_{N}, W_{N} and the like that are control terminals are led out from the second side surface 4b. The first side surface 4a on the power output side has a smaller number of terminals than that of the second side surface 4b on the control terminal side, and hence an insulating distance between the terminals can be more easily ensured than the first embodiment.

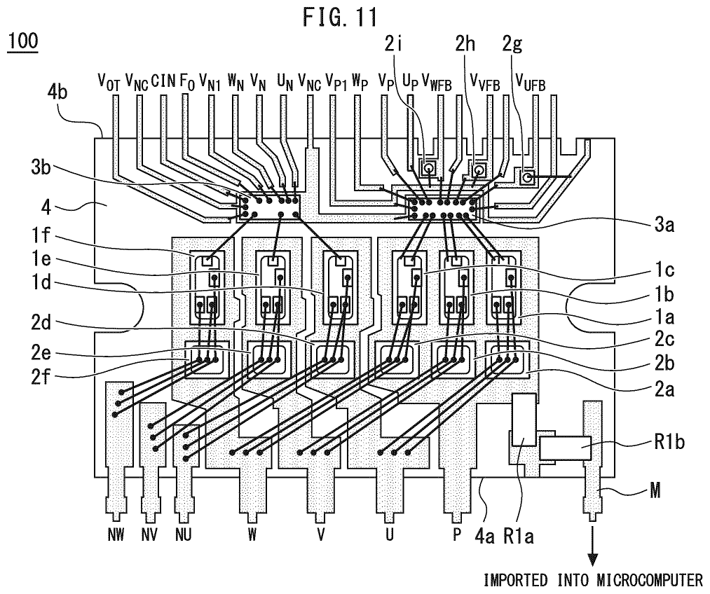

FIG. 11 is a plan view illustrating a modification example of the transfer molded module according to the second embodiment. In place of the resistor R1, a plurality of resistors R1a and R1b connected in series are provided. A resistance value of each of the resistors R1a and R1b is 1 to 2 MΩ. This makes it possible to monitor a high bus voltage even when a rated voltage or rated power is exceeded with a single resistor. Further, using a plurality of resistors R1a and R1b can avoid layout restrictions to be caused by the size of the chip resistor.

### Third Embodiment

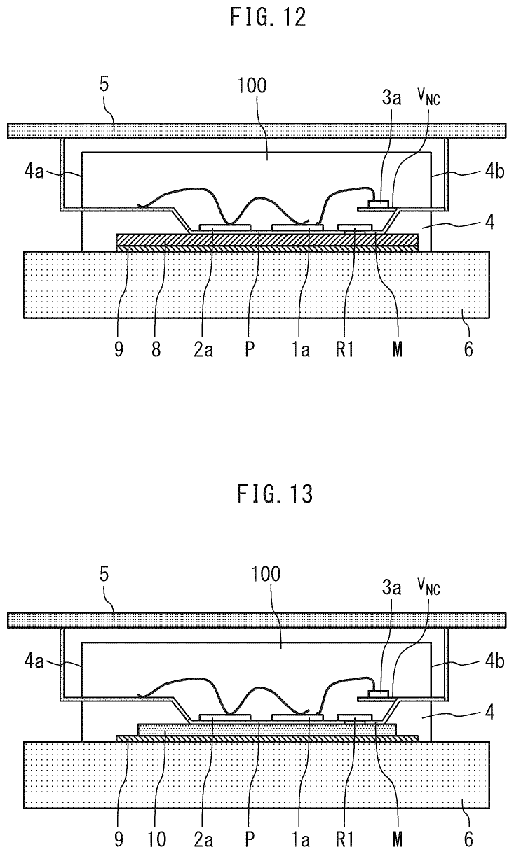

FIG. 12 is a sectional view illustrating a semiconductor device according to a third embodiment. In this embodiment, an insulating sheet 8 is bonded to lower surfaces of the monitoring terminal M and the die pad portions of the terminals P, U, V, and W on which the power devices 1a to 1f and the diodes 2a to 2f are mounted. A metal film 9 is provided as a heat dissipation mechanism on a lower surface of the insulating sheet 8. The metal film 9 is exposed from a lower surface of the encapsulating resin 4 as a heat dissipation plate. With the exposed metal film 9 being connected to the heatsink 6, the heat of the power devices 1a to 1f can be dissipated to the heatsink 6 via the insulating sheet 8 and the metal film 9. Moreover, the heat of the resistor R1 for monitoring the bus voltage can also be dissipated to the heatsink 6.

The material of the insulating sheet 8 is, for example, epoxy resin having thermal conductivity, but may be any material having a function of causing the lead frame and the metal film 9 to adhere to each other, having electrical insulation, and having high thermal conductivity. The insulating sheet 8 may be resin containing at least one filler of silicon oxide (SiO₂), aluminum oxide (Al₂O₃), and boron nitride (BN). The material of the metal film 9 is only required to be a material having high thermal conductivity, and is, for example, Al or Cu. Depending on the purpose of the semiconductor device, the metal film 9 may be a copper foil having a thickness of several tens of micrometers, or may be an aluminum plate or a copper plate having a thickness of several millimeters to several tens of millimeters.

### Fourth Embodiment

FIG. 13 is a sectional view illustrating a semiconductor device according to a fourth embodiment. In this embodiment, an insulating substrate 10 is provided below the monitoring terminal M and the die pad portions of the terminals P, U, V, and W on which the power devices 1a to 1f and the diodes 2a to 2f are mounted. The material of the insulating substrate 10 is ceramics, but the material is not limited thereto and is only required to be an insulating member. The metal film 9 is provided as a heat dissipation mechanism on a lower surface of the insulating substrate 10. The metal film 9 is exposed from the lower surface of the encapsulating resin 4 as a heat dissipation plate. With the exposed metal film 9 being connected to the heatsink 6, the heat of the power devices 1a to 1f can be dissipated to the heatsink 6 via the insulating substrate 10 and the metal film 9. Moreover, the heat of the resistor R1 for monitoring the bus voltage can also be dissipated to the heatsink 6. It is to be noted that, in place of the lead frame, a circuit pattern present on an upper surface of the insulating substrate 10 may be used. In this case, separate members may be prepared as the terminals P, U, V, and W.

The configurations described in the embodiments and modification examples above can be combined with each other. Further, the configurations can be partially omitted or modified without departing from the gist of the present disclosure.

The power devices 1a to 1f and the diodes 2a to 2f are not limited to semiconductor chips formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor chip formed of such a wide-bandgap semiconductor has a high voltage resistance and a high allowable current density, and thus can be miniaturized. The use of such a miniaturized semiconductor chip enables the miniaturization and high integration of the semiconductor device in which the semiconductor chip is incorporated. Further, since the semiconductor chip has a high heat resistance, a radiation fin of a heatsink can be miniaturized and a water-cooled part can be air-cooled, which leads to further miniaturization of the semiconductor device. Further, since the semiconductor chip has a low power loss and a high efficiency, a highly efficient semiconductor device can be achieved. Both the power devices 1a to 1f and the diodes 2a to 2f are desirably formed of a wide-bandgap semiconductor. However, only one of the power devices 1a to 1f and the diodes 2a to 2f may be formed of a wide-bandgap semiconductor. Also in this case, the advantageous effects described in this embodiment can be obtained.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### Supplementary Note 1

A transfer molded module comprising:
a p-side frame;
an n-side frame;
a high-side first power device connected to the p-side frame;
a low-side second power device connected to the n-side frame;
a monitoring terminal;
a resistor connected between the p-side frame and the monitoring terminal; and
an encapsulating resin encapsulating the p-side frame, the n-side frame, the first power device, the second power device, the monitoring terminal, and the resistor,
wherein the p-side frame, the n-side frame, and the monitoring terminal are led out from a side surface of the encapsulating resin.

### Supplementary Note 2

The transfer molded module according to Supplementary Note 1, wherein the first power device is mounted on the p-side frame,
the resistor is joined to a part of the monitoring terminal bent downward and the p-side frame, and
the resistor is positioned at the same height as the first power device in the encapsulating resin.

### Supplementary Note 3

The transfer molded module according to Supplementary Note 1 or 2, further comprising:
a first control device controlling the first power device;
a second control device controlling the second power device;
a first control inputting a control signal to the first control device; and
a second control inputting a control signal to the second control device,
wherein the side surface of the encapsulating resin includes a first side surface and a second side surface that are opposed to each other,
the p-side frame and the n-side frame are led out from the first side surface, and
the first control terminal, the second control terminal, and the monitoring terminal are led out from the second side surface.

### Supplementary Note 4

The transfer molded module according to Supplementary Note 1 or 2, further comprising:
a first control device controlling the first power device;
a second control device controlling the second power device;
a first control inputting a control signal to the first control device; and
a second control inputting a control signal to the second control device,
wherein the side surface of the encapsulating resin includes a first side surface and a second side surface that are opposed to each other,
the p-side frame, the n-side frame, and the monitoring terminal are led out from the first side surface, and
the first control terminal and the second control terminal are led out from the second side surface.

### Supplementary Note 5

The transfer molded module according to any one of Supplementary Notes 1 to 4, wherein the resistor includes a plurality of resistors connected in series.

### Supplementary Note 6

The transfer molded module according to any one of Supplementary Notes 1 to 5, wherein a lower side of the p-side frame, the n-side frame, and the monitoring terminal is covered with the encapsulating resin.

### Supplementary Note 7

The transfer molded module according to any one of Supplementary Notes 1 to 5, further comprising an insulating sheet bonded to lower surfaces of the p-side frame, the n-side frame, and the monitoring terminal.

### Supplementary Note 8

The transfer molded module according to any one of Supplementary Notes 1 to 5, further comprising an insulating substrate provided below the p-side frame, the n-side frame, and the monitoring terminal.

### Supplementary Note 9

The transfer molded module according to any one of Supplementary Notes 1 to 8, wherein the first power device and the second power device are formed of a wide-bandgap semiconductor.

### Reference Signs List

1a-1c power device (first power device); 1d-1f power device (second power device); 3a first control device; 3b second control device; 4 encapsulating resin; 4a first side surface; 4b second side surface; 8 insulating sheet; 10 insulating substrate; M monitoring terminal; P terminal (p-side frame); R1,R1a,R1b resistor; U, V, W terminal (n-side frame); UP, VP, WP terminal (first control terminal); UN, VN, WN terminal (second control terminal)

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2025-037699, filed on Mar. 10, 2025 including specification, claims, drawings and summary, on which the convention priority of the present application is based, is incorporated herein by reference in its entirety.

1. A transfer molded module comprising:
a p-side frame;
an n-side frame;
a high-side first power device connected to the p-side frame;
a low-side second power device connected to the n-side frame;
a monitoring terminal;
a resistor connected between the p-side frame and the monitoring terminal; and
an encapsulating resin encapsulating the p-side frame, the n-side frame, the first power device, the second power device, the monitoring terminal, and the resistor,
wherein the p-side frame, the n-side frame, and the monitoring terminal are led out from a side surface of the encapsulating resin.

2. The transfer molded module according to claim 1, wherein the first power device is mounted on the p-side frame,
the resistor is joined to a part of the monitoring terminal bent downward and the p-side frame, and
the resistor is positioned at the same height as the first power device in the encapsulating resin.

3. The transfer molded module according to claim 1, further comprising:
a first control device controlling the first power device;
a second control device controlling the second power device;
a first control inputting a control signal to the first control device; and
a second control inputting a control signal to the second control device,
wherein the side surface of the encapsulating resin includes a first side surface and a second side surface that are opposed to each other,
the p-side frame and the n-side frame are led out from the first side surface, and
the first control terminal, the second control terminal, and the monitoring terminal are led out from the second side surface.

4. The transfer molded module according to claim 1, further comprising:
a first control device controlling the first power device;
a second control device controlling the second power device;
a first control inputting a control signal to the first control device; and
a second control inputting a control signal to the second control device,
wherein the side surface of the encapsulating resin includes a first side surface and a second side surface that are opposed to each other,
the p-side frame, the n-side frame, and the monitoring terminal are led out from the first side surface, and
the first control terminal and the second control terminal are led out from the second side surface.

5. The transfer molded module according to claim 1, wherein the resistor includes a plurality of resistors connected in series.

6. The transfer molded module according to claim 1, wherein a lower side of the p-side frame, the n-side frame, and the monitoring terminal is covered with the encapsulating resin.

7. The transfer molded module according to claim 1, further comprising an insulating sheet bonded to lower surfaces of the p-side frame, the n-side frame, and the monitoring terminal.

8. The transfer molded module according to claim 1, further comprising an insulating substrate provided below the p-side frame, the n-side frame, and the monitoring terminal.

9. The transfer molded module according to claim 1, wherein the first power device and the second power device are formed of a wide-bandgap semiconductor.
